(19) United States
(12) Patent Application Publication
(10) Pub. No.: US 2015/0027977 A1
(43) Pub. Date: Jan. 29, 2015

(54) METHOD OF MANUFACTURING WIRING BOARD

(71) Applicant: KYOCERA SLC Technologies Corporation, Yasu-shi (JP)

(72) Inventors: Kohichi OHSUMI, Yasu-shi (JP); Sumiko NOGUCHI, Otsu-shi (JP)

(73) Assignee: KYOCERA SLC Technologies Corporation, Yasu-shi (JP)

(21) Appl. No.: 14/341,004

(22) Filed: Jul. 25, 2014

(30) Foreign Application Priority Data
Jul. 29, 2013 (JP) 2013-156675

(51) Int. Cl. H05K 3/06; H05K 3/07

(52) U.S. Cl. CPC H05K 3/061; H05K 3/07; H05K 2203/0369; H05K 2203/0548; H05K 2203/0582
USPC 216/13

(57) ABSTRACT

A manufacturing method includes a step of forming a first plating mask on a base metal layer, a step of forming a main conductor layer on the base metal layer exposed from the first plating mask, a step of forming a second plating mask on them, a step of attaching a metal plating layer to an upper surface of the main conductor layer exposed from the second plating mask, a step of removing the first and second plating masks, a step of etching away a portion of the base metal layer to which the main conductor layer is not attached, and a step of forming a solder resist layer.

### BACKGROUND OF THE INVENTION

(1) Field of the Invention

The present invention relates to a method of manufacturing a wiring board for mounting a semiconductor element such as a semiconductor integrated circuit element.

(2) Description of the Related Art

The wiring board for mounting the semiconductor element has a copper wiring conductor for being electrically connected to the semiconductor element, on an upper surface of an insulating board. Furthermore, a solder resist layer is attached to the upper surface of the insulating board in such a manner that the wiring conductor which is electrically connected to the semiconductor element is partially exposed. In addition, a metal plating layer which is superior in solder wettability is attached to a surface of the wiring conductor which is exposed from the solder resist layer. Thus, an electrode of the semiconductor element is connected to the wiring conductor having the attached metal plating layer, with a solder. As the metal plating layer superior in solder wettability, gold plating layer having a nickel plating layer as a base is normally used.

As for the wiring board, JP 2006-120667 A discloses a method of manufacturing the wiring board in which the wiring conductor and the solder resist layer are formed on the upper surface of the insulating board, and the metal plating layer is attached to the wiring conductor which is exposed from the solder resist layer. This conventional method will be described with reference to FIGS. 13 to 24. In addition, FIGS. 13 to 24 are enlarged perspective views in respective steps, in which only one portion of the wiring board is shown.

First, as shown in FIG. 13, a base metal layer 12a serving as the wiring conductor is attached all over an upper surface of an insulating board 11. The base metal layer 12a is composed of electroless copper plating layer or ultrathin copper foil.

Next, as shown in FIG. 14, a first plating mask 18 is formed on the base metal layer 12a. The first plating mask 18 is provided so as to expose the base metal layer 12a into a shape corresponding to the wiring conductor.

Next, as shown in FIG. 15, a main conductor layer 12b composed of an electrolytic copper plating layer is attached to the base metal layer 12a which is exposed from the first plating mask 18.

Next, as shown in FIG. 16, the first plating mask 18 is peeled and removed.

Next, as shown in FIG. 17, an etching mask 19 is formed. The etching mask 19 partially covers the base metal layer 12a and the main conductor layer 12b formed thereon so as to stride across a plurality of patterns of the main conductor layer 12b.

Next, as shown in FIG. 18, at a portion which is exposed from the etching mask 19, a portion of the base metal layer 12a which is not attached with the main conductor layer 12b is etched away.

Next, as shown in FIG. 19, the etching mask 19 is peeled and removed. At this time, the plurality of the patterns of the main conductor layer 12b are in a connected state electrically to each other with the base metal layer 12a which is left without being etched away, between them.

Next, as shown in FIG. 20, a second plating mask 20 is formed so as to partially expose the base metal layer 12a and the main conductor layer 12b to which a metal plating layer is to be attached. The second plating mask 20 is provided so as to completely cover the base metal layer 12a which is left without being etched away, between the adjacent patterns of the main conductor layer 12b.

Next, as shown in FIG. 21, a metal plating layer 17 is attached by electrolytic plating to surfaces of the base metal layer 12a and the main conductor layer 12b which are exposed from the second plating mask 20. At this time, electric charges used for the electrolytic plating are supplied through the base metal layer 12a which is left without being etched away, between the patterns of the main conductor layer 12b.

Next, as shown in FIG. 22, the second plating mask 20 is peeled and removed.

Next, as shown in FIG. 23, a portion of the base metal layer 12a which is left without being etched away, between the patterns of the main conductor layer 12b is etched away. Thus, a wiring conductor 12 is formed such that it is composed of the base metal layer 12a and the main conductor layer 12b, and its side surface and upper surface is partially attached with the metal plating layer 17, in an electrically independent state from the other.

Finally, as shown in FIG. 24, a solder resist layer 13 is formed so as to have an opening 13a to expose a portion of the wiring conductor 12 which is attached with the metal plating layer 17. Thus, the wiring board is completed.

However, according to the above-described conventional method of manufacturing the wiring board, the metal plating layer 17 is attached all over the upper surface and the side surface of the wiring conductor 12 which are exposed from the solder resist layer 13. Therefore, an insulating interval between the adjacent wiring conductors 12 is narrowed by the metal plating layer 17 attached to the side surface of the wiring conductor 12. In addition, the metal plating layer 17 attached to the side surface of the wiring conductor 12 is superior in solder wettability. Therefore, at the time of connecting the electrode of the semiconductor element to the wiring conductor 12 having the attached metal plating layer 17, with a solder, the solder wets and spreads to the side surface of the wiring conductor 12. Therefore, in a case where the interval between the adjacent wiring conductors 12 is as narrow as 20 μm or less, it is highly likely that the electrical insulating property between the adjacent wiring conductors 12 is damaged by the solder which has wetted and spread to the side surface of the wiring conductor 12. Furthermore, the etching process needs to be performed two times for a portion of the base metal layer 12a to which the main conductor layer 12b is not attached, which complicates the manufacturing process.

### SUMMARY OF THE INVENTION

An object of the present invention is to provide a method of manufacturing a wiring board in which electrical insulating reliability is high between adjacent wiring conductors, in a simple manner.

Other objects and advantages of the present invention will become apparent from the following description.

A method of manufacturing a wiring board according to the present invention includes:

(1) a step of attaching a base metal layer serving as a wiring conductor on an upper surface of an insulating board;

(2) a step of forming a first plating mask on the base metal layer to expose the base metal layer into a shape corresponding to the wiring conductor;

(3) a step of attaching a main conductor layer serving as the wiring conductor by electrolytic plating, on the base metal layer exposed from the first plating mask;

(4) a step of forming a second plating mask on the first plating mask and the main conductor layer, to expose an upper surface of the main conductor layer having a portion corresponding to a semiconductor element connection pad;

(5) a step of attaching a metal plating layer by electrolytic plating to the upper surface of the main conductor layer exposed from the first and second plating masks;

(6) a step of removing the first and second plating masks;

(7) a step of etching away a portion of the base metal layer to which the main conductor layer is not attached, and forming the wiring conductor composing of the base metal layer and the main conductor layer, and having the metal plating layer attached to the upper surface of the semiconductor element connection pad; and

(8) a step of forming a solder resist layer having an opening to expose the semiconductor element connection pad, on the insulating board and the wiring conductor.

According to the present invention, at the time of attaching the metal plating layer to the main conductor layer serving as the wiring conductor, the side surface of the main conductor layer is covered with the first plating mask. Therefore, the metal plating layer is not attached to the side surface of the main conductor layer. Therefore, an electrical insulating interval between the adjacent wiring conductors is not narrowed by the metal plating layer. Furthermore, the side surface of the semiconductor element connection pad is inferior in solder wettability because the metal plating layer is not attached. Therefore, at the time of connecting the electrode of the semiconductor element to the semiconductor element connection pad with a solder, the solder does not wet and spread to the side surface of the semiconductor element connection pad, so that electrical insulating properties between the adjacent wiring conductors can be preferably maintained.

Furthermore, the etching process only needs to be performed once for a portion of the base metal layer to which the main conductor layer is not attached, so that the manufacturing process can be simplified.

### BRIEF DESCRIPTION OF THE DRAWINGS

FIG. 1 is a schematic cross-sectional view of a wiring board manufactured by a manufacturing method according to one embodiment of the present invention;

FIG. 2 is a schematic top view of the wiring board shown in FIG. 1;

FIG. 3 is an essential part enlarged cross-sectional view of the wiring board shown in FIG. 1;

FIG. 4 is an essential part enlarged perspective view to describe a method of manufacturing the wiring board according to the one embodiment of the present invention;

FIG. 5 is an essential part enlarged perspective view to describe the method of manufacturing the wiring board according to the one embodiment of the present invention;

FIG. 6 is an essential part enlarged perspective view to describe the method of manufacturing the wiring board according to the one embodiment of the present invention;

FIG. 7 is an essential part enlarged perspective view to describe the method of manufacturing the wiring board according to the one embodiment of the present invention;

FIG. 8 is an essential part enlarged perspective view to describe the method of manufacturing the wiring board according to the one embodiment of the present invention;

FIG. 9 is an essential part enlarged perspective view to describe the method of manufacturing the wiring board according to the one embodiment of the present invention;

FIG. 10 is an essential part enlarged perspective view to describe the method of manufacturing the wiring board according to the one embodiment of the present invention;

FIG. 11 is an essential part enlarged perspective view to describe the method of manufacturing the wiring board according to the one embodiment of the present invention;

FIG. 12 is an essential part enlarged perspective view to describe a method of manufacturing a wiring board according to another embodiment of the present invention and;

FIGS. 13 to 24 are essential part enlarged perspective views to describe steps of manufacturing a conventional wiring board.

### DESCRIPTION OF THE PREFERRED EMBODIMENTS

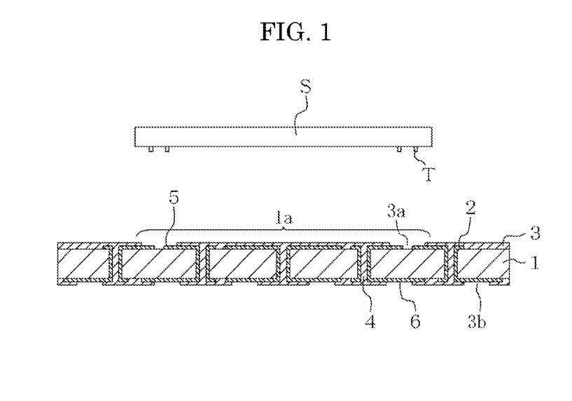

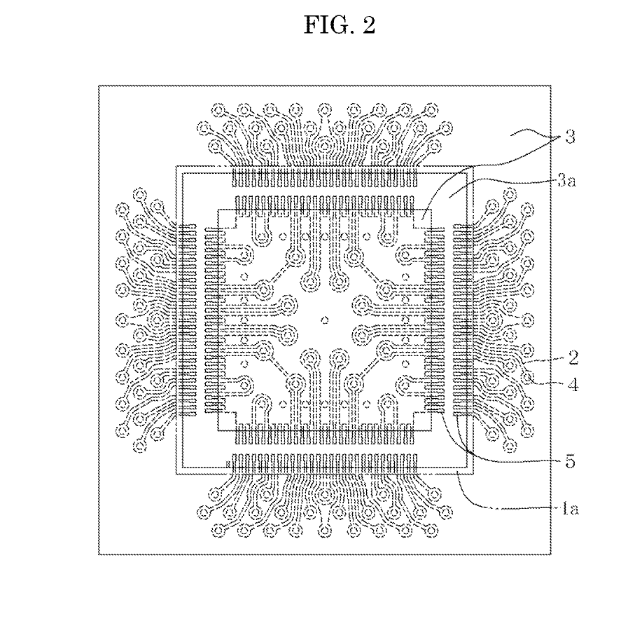

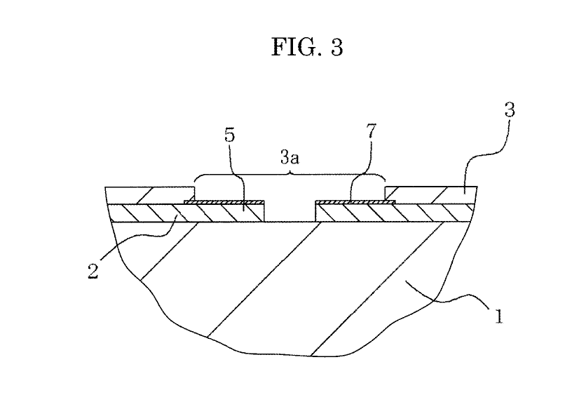

Next, the method of manufacturing the wiring board in the present invention will be described with reference to the accompanying drawings. FIG. 1 is a schematic cross-sectional view showing an example of the wiring board manufactured by the method in the present invention. FIG. 2 is a schematic top view of the wiring board shown in FIG. 1. FIG. 3 is an essential part enlarged cross-sectional view of the wiring board shown in FIG. 1.

This wiring board includes an insulating board 1, a wiring conductor 2, and a solder resist layer 3. In FIG. 2, broken lines show a portion of the wiring conductor 2 provided on an upper surface of the insulating board 1 and covered with the solder resist layer 3.

The insulating board 1 is composed of resin electrically insulating material formed by thermally curing a single or multiple insulating layers. The insulating layer is provided by impregnating a glass cloth base material with a thermoset resin such as epoxy resin or bismaleimide triazine resin, for example. The insulating board 1 is about 30 μm to 200 μm in thickness. The insulating board 1 has a mounting portion la for mounting a semiconductor element S, in a center of its upper surface. The insulating board 1 has through-holes 4 formed so as to extend from its upper surface to lower surface. Each of the through-holes 4 is about 50 μm to 300 μm, preferably about 50 μm to 150 μm in diameter.

The wiring conductor 2 is made of copper, and drawn from the mounting portion la on the upper surface of the insulating board 1 to the lower surface of the insulating board 1 through inner walls of the through-holes 4. The wiring conductor 2 is about 10 μm to 20 μm in thickness. The wiring conductor 2 on the upper surface of the insulating board 1 has many semiconductor element connection pads 5 around an outer periphery of the mounting portion 1a. Each of the semiconductor element connection pads 5 is about 10 μm to 30 μm in width, and about 40 μm to 150 μm in length. These semiconductor element connection pads 5 are arranged in two rows such as an inside row of the wiring board and an outside row of the wiring board, along outer peripheral sides of the semiconductor element S as shown in FIG. 2. In addition, the wiring conductor 2 on the lower surface of the insulating board 1 has many external connection pads 6. Each of the external connection pads 6 is about 200 μm to 500 μm in diameter. These external connection pads 6 are arranged in a lattice shape on the lower surface of the insulating board 1. The semiconductor element connection pad 5 and the external connection pad 6 are electrically connected to each other through the wiring conductor 2.

The solder resist layer 3 is composed of thermoset resin such as epoxy resin, and attached to the upper and lower surfaces of the insulating board 1 and fills the through-holes 4. The solder resist layer 3 is about 20 μm to 40 μm in thickness in the portion attached to the upper and lower surfaces of the insulating board 1. The solder resist layer 3 has an opening 3a formed on a side of the upper surface of the insulating board 1 so as to expose the semiconductor element connection pads 5. The opening 3a has a rectangular frame shape along the outer periphery of the mounting portion 1a so as to collectively expose the semiconductor element connection pads 5 arranged in the two inside and outside rows. In addition, the solder resist layer 3 has openings 3b on a side of the lower surface of the insulating board 1 so as to expose the external connection pads 6. The opening 3b has a circular shape to expose each of the external connection pads 6 individually.

Thus, according to the wiring board, the semiconductor element S is arranged on the mounting portion la so that each electrode terminal T is opposed to the corresponding semiconductor element connection pad 5, and then the electrode terminal T and the semiconductor element connection pad 5 are connected with a solder. In this way, the semiconductor element S is mounted on the mounting portion 1a.

Furthermore, according to the wiring board, as shown in FIG. 3, a metal plating layer 7 superior in solder wettability is attached to the upper surface of the semiconductor element connection pad 5. The metal plating layer 7 is composed of a nickel plating layer and a gold plating layer provided thereon, and attached by electrolytic plating. The nickel plating layer is about 0.05 μm to 10 μm, preferably about 1 μm to 5 μm in thickness, and the gold plating layer is about 0.5 μm to 2 μm in thickness. The metal plating layer 7 improves the solder wettability of the semiconductor element connection pad 5.

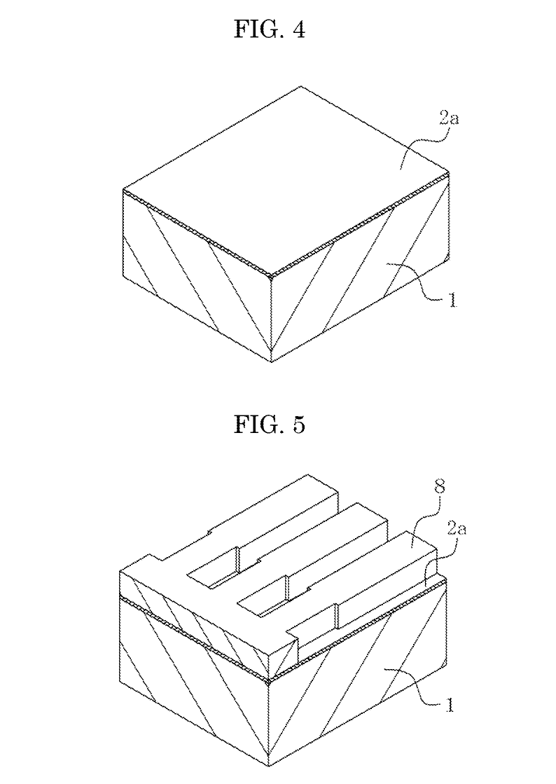

Next, the method of manufacturing the wiring board in the present invention will be described with reference to FIGS. 4 to 11. FIGS. 4 to 11 are enlarged perspective views in respective steps, in which only the neighborhood of the semiconductor element connection pad 5 is shown in the example of the above-described wiring board.

First, as shown in FIG. 4, a base metal layer 2a serving as the wiring conductor 2 is attached all over the upper surface of the insulating board 1. The base metal layer 2a is composed of an electroless copper plating layer having a thickness of about 0.1 μm to 1 μm, for example. Alternatively, the base metal layer 2a may be copper foil having a thickness of about 1 μm to 3 μm. Furthermore, the base metal layer 2a may be provided such that an electroless copper plating layer having a thickness of about 0.1 μm to 1 μm is attached to a surface of the copper foil having the thickness of about 1 μm to 3 μm.

Next, as shown in FIG. 5, a first plating mask 8 is formed on the base metal layer 2a. The first plating mask 8 is formed by photolithography so as to expose the base metal layer 2a into a shape corresponding to the wiring conductor 2.

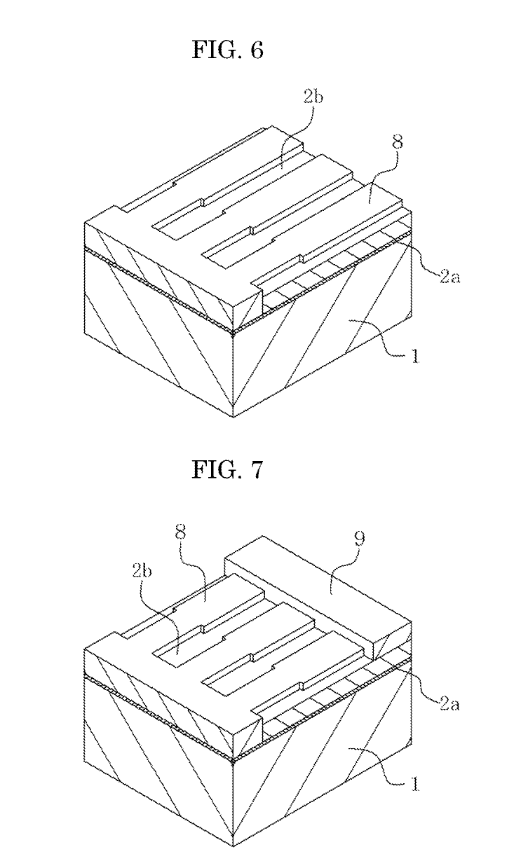

Next, as shown in FIG. 6, a main conductor layer 2b composed of an electrolytic copper plating layer is attached to the base metal layer 2a exposed from the first plating mask 8. The main conductor layer 2b is about 5 μm to 25 μm in thickness, and formed such that electrolytic copper plating is performed while electric charges used for the electrolytic plating are supplied from the base metal layer 2a.

Next, as shown in FIG. 7, a second plating mask 9 is formed on the first plating mask 8 and on the main conductor layer 2b. The second plating mask 9 is formed by photolithography so as to expose an area on an upper surface of the main conductor layer 2b to which the metal plating layer 7 is to be attached.

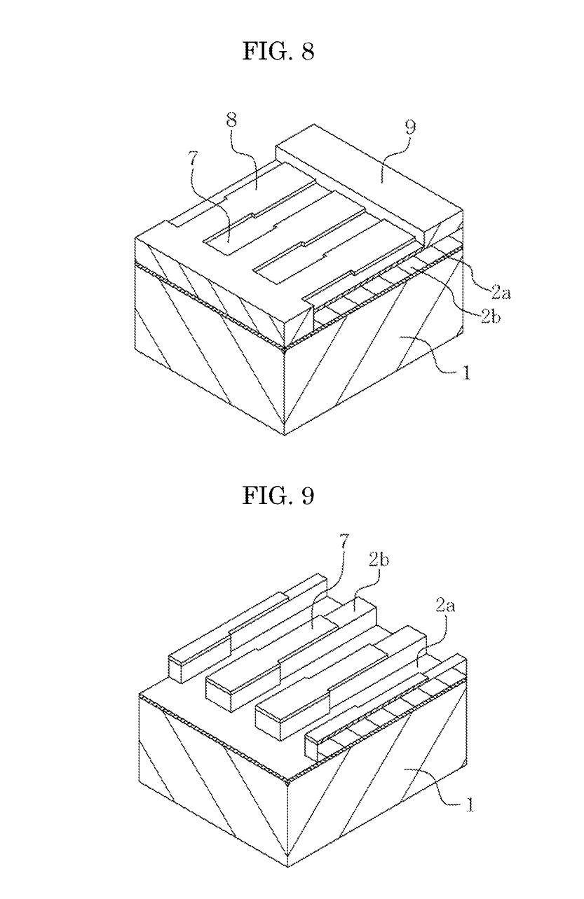

Next, as shown in FIG. 8, the metal plating layer 7 is attached to the surface of the main conductor layer 2b which is exposed from the first plating mask 8 and the second plating mask 9. The metal plating layer 7 is formed by sequentially attaching the nickel plating layer having a thickness of about 0.05 μm to 10 μm, preferably about 1 μm to 5 μm and a gold plating layer having a thickness of about 0.1 μm to 2 μm. Thus, the metal plating layer 7 is formed by sequentially performing electrolytic nickel plating and electrolytic gold plating while supplying electric charges used for the electrolytic plating from the base metal layer 2a.

Next, as shown in FIG. 9, the first plating mask 8 and the second plating mask 9 are peeled and removed.

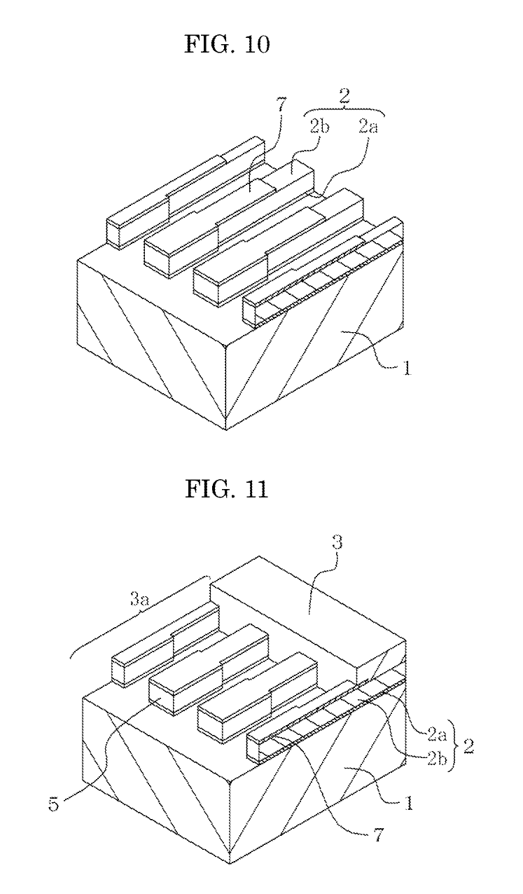

Next, as shown in FIG. 10, a portion of the base metal layer 2a which is not covered with the main conductor layer 2b is etched away. Thus, the wiring conductor 2 is formed of the remained base metal layer 2a and the main conductor layer 2b. The wiring conductor 2 includes the above-described semiconductor element connection pads 5.

Finally, as shown in FIG. 11, the solder resist layer 3 is formed on the insulating board 1 and the wiring conductor 2. The solder resist layer 3 is formed by photolithography so as to have the opening 3a to expose the semiconductor element connection pads 5.

In this way, the present invention provides the wiring board in which the metal plating layer 7 composed of the nickel plating layer and the gold plating layer is attached to the upper surface of the semiconductor element connection pad 5 which is exposed in the opening 3a of the solder resist layer 3.

According to this wiring board, the metal plating layer 7 is not attached to a side surface of the semiconductor element connection pad 5. Therefore, an electrical insulating interval between the adjacent semiconductor element connection pads 5 is not narrowed by the metal plating layer 7.

In addition, since the side surface of the semiconductor element connection pad 5 does not attached the metal plating layer 7, it is inferior in solder wettability. Therefore, at the time of connecting the electrode T of the semiconductor element S to the semiconductor element connection pad 5 with the solder, the solder does not wet and spread to the side surface of the semiconductor element connection pad 5, so that the electrical insulating property can be preferably maintained between the adjacent wiring conductors 2.

Furthermore, the present invention is not limited to the above example, and can be variously modified or improved within the claimed scope of the invention.

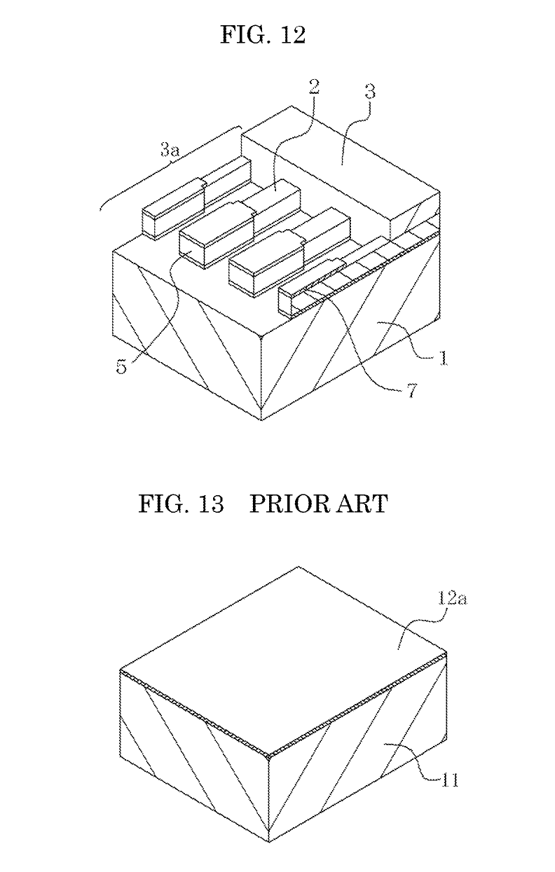

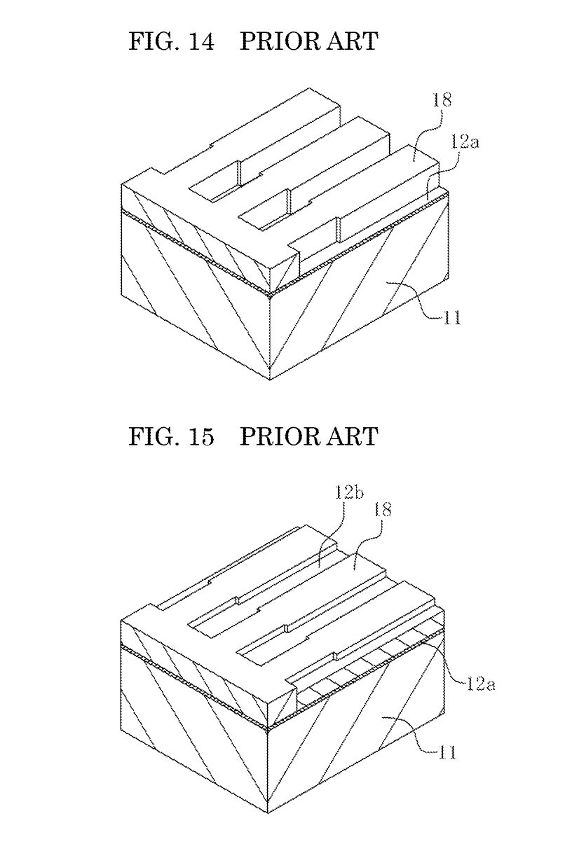

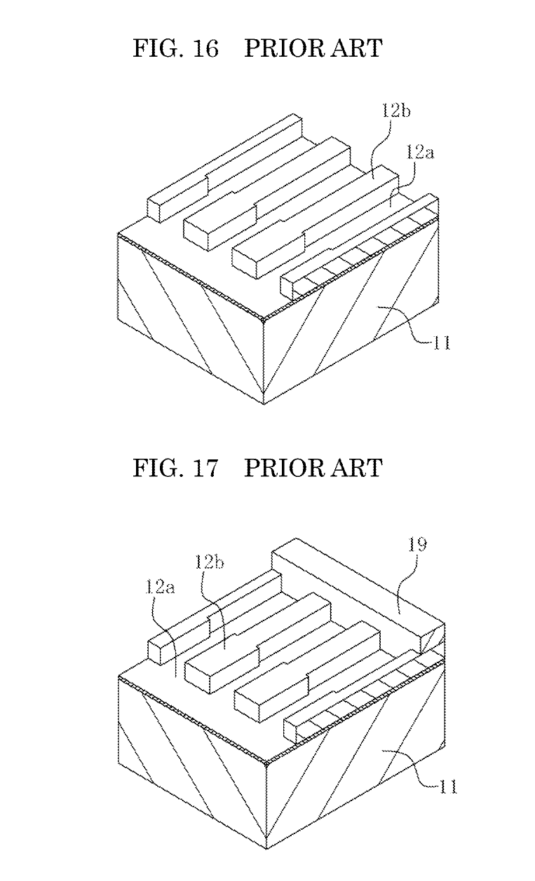

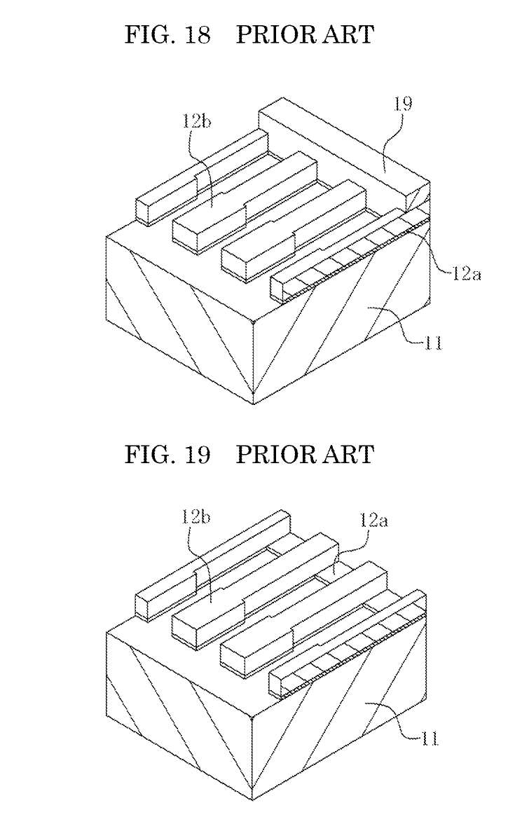

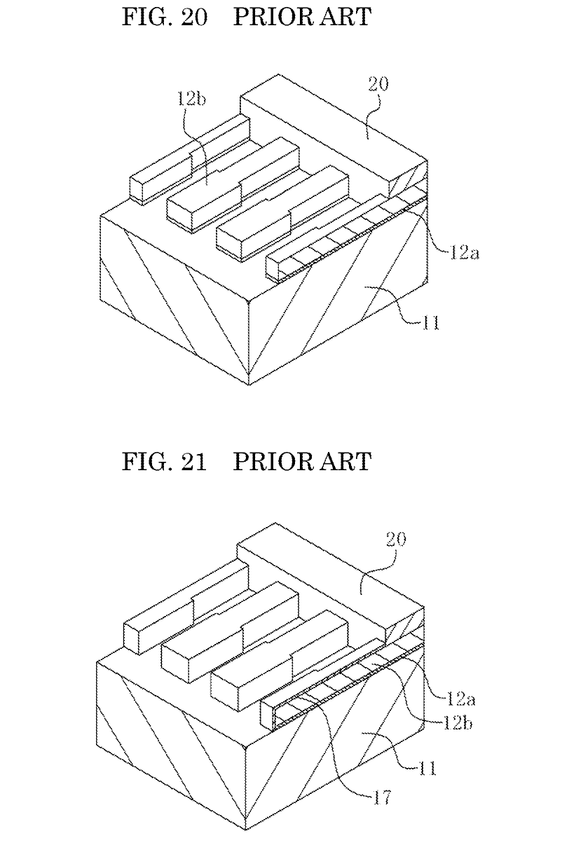

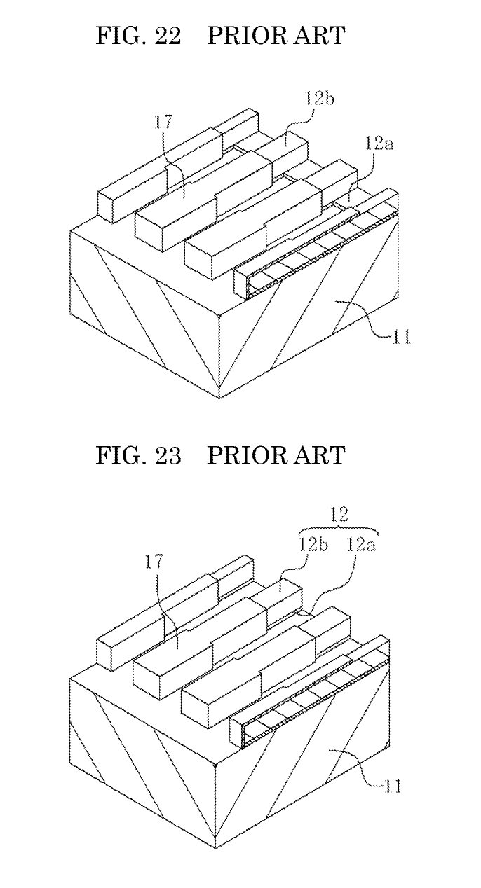

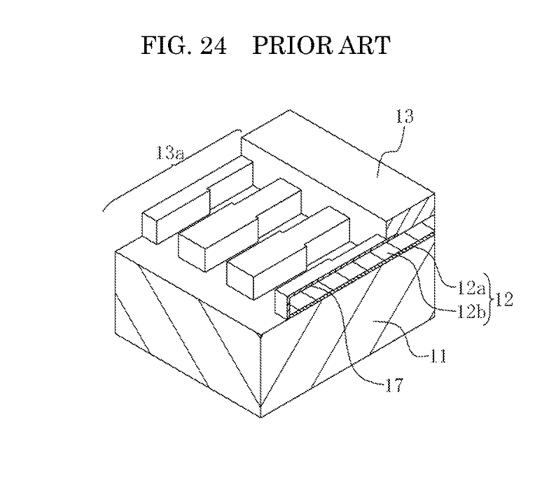

For example, in the above example, the metal plating layer 7 is attached all over the upper surface of the wiring conductor 2 which is exposed from the opening 3a of the solder resist layer 3, but the metal plating layer 7 may be only attached to the upper part of the semiconductor element connection pad 5 and its neighborhood on the upper surface of the wiring conductor 2, as shown in FIG. 12. In this case, the wiring conductor 2 exposed from the opening 3a of the solder resist layer 3 is superior in solder wettability only on the semiconductor element connection pad 5 attaching the metal plating layer 7 and in its neighborhood, and inferior in solder wettability in the rest of it. Therefore, at the time of connecting the electrode T of the semiconductor element S to the semiconductor element connection pad 5 with the solder, the solder does not wet and spread greatly from the semiconductor element connection pad 5 to the rest of the wiring conductor 2, and it is possible to preferably form a meniscus of the solder which connects the electrode T of the semiconductor element S to the semiconductor element connection pad 5, so that both of them can be firmly connected.

What is claimed is:

1. A method of manufacturing a wiring board comprising:
a step of attaching a base metal layer serving as a wiring conductor to an upper surface of an insulating board;
a step of forming a first plating mask on the base metal layer to expose the base metal layer into a shape corresponding to the wiring conductor;
a step of attaching a main conductor layer serving as the wiring conductor by electrolytic plating, on the base metal layer exposed from the first plating mask;
a step of forming a second plating mask on the first plating mask and the main conductor layer, to expose an upper surface of the main conductor layer having a portion corresponding to a semiconductor element connection pad; a step of attaching a metal plating layer by electrolytic plating to the upper surface of the main conductor layer exposed from the first and second plating masks;
a step of removing the first and second plating masks;
a step of etching away a portion of the base metal layer to which the main conductor layer is not attached, and forming the wiring conductor comprising the base metal layer and the main conductor layer, and having the metal plating layer attached to the upper surface of the semiconductor element connection pad; and
a step of forming a solder resist layer having an opening to expose the semiconductor element connection pad, on the insulating board and the wiring conductor.

2. The method of manufacturing the wiring board according to claim 1, wherein
the metal plating layer comprises a nickel plating layer and a gold plating layer formed on the nickel plating layer.

3. The method of manufacturing the wiring board according to claim 1, wherein
the metal plating layer is attached by electrolytic plating all over the upper surface of the main conductor layer exposed from the first and second plating masks.

4. The method of manufacturing the wiring board according to claim 1, wherein
the metal plating layer is attached by electrolytic plating to the semiconductor element connection pad and a neighborhood of the semiconductor element connection pad on the upper surface of the main conductor layer exposed from the first and second plating masks.
